(19) United States
(12) Patent Application Publication
(10) Pub. No.: US 2012/0247667 A1
(43) Pub. Date: Oct. 4, 2012

(54) PLASMA TREATMENT APPARATUS

(75) Inventors: Hisashi HASHIGUCHI, Mie (JP); Hideo Eto, Mie (JP); Makoto Saito, Mie (JP)

(73) Assignee: KABUSHIKI KAISHA TOSHIBA, Tokyo (JP)

(21) Appl. No.: 13/232,232

(22) Filed: Sep. 14, 2011

(30) Foreign Application Priority Data
Apr. 4, 2011 (JP) 2011-082666

(51) Int. Cl. H01L 21/3065

(52) U.S. Cl. 156/345.3

(57) ABSTRACT

According to an embodiment, a plasma treatment apparatus includes a processing target holding unit and a plasma generation unit in a chamber. The processing target holding unit includes a supporting table on which a wafer is mounted, a ring-shaped insulator ring arranged at an outer periphery of the supporting table, and a protective film containing yttria for covering a side surface section and an upper surface section of the insulator ring. The protective film is formed thicker on the upper surface section than on the side surface section of the insulator ring.

### CROSS-REFERENCE TO RELATED APPLICATIONS

This application is based upon and claims the benefit of priority from the prior Japanese Patent Application No. 2011-82666, filed on Apr. 4, 2011; the entire contents of which are incorporated herein by reference.

### FIELD

Embodiments described herein relate generally to a plasma treatment apparatus.

### BACKGROUND

The plasma treatment apparatus has a structure in which a substrate holding unit, which functions as a lower electrode and which holds a wafer, and a shower head, which functions as an upper electrode and which supplies gas in shower form, are arranged facing each other in a chamber. In such plasma treatment apparatus, gas is supplied from the shower head into the chamber, and radio frequency power is supplied to the substrate holding unit to generate plasma, thus removing an oxide film or the like on the wafer held by the substrate holding unit.

Generally, the substrate holding unit includes an electrostatic chuck section, which is arranged in a region where the wafer is mounted and which holds the wafer with an electrostatic chuck mechanism, an annular focus ring arranged to surround the outer periphery of the wafer mounted in the electrostatic chuck section, and an annular insulator ring, which is arranged to surround the outer periphery of the focus ring and which insulates between the apparatus main body, and the lower electrode and the focus ring. The focus ring is generally made from a conductive material such as silicon (Si), and the insulator ring is generally made from quartz that is easy to process and that has an insulating property.

However, in the prior art technique, the configuring members of the substrate holding unit such as the insulator ring tend to be etched when etching the wafer since the plasma is generated over a region wider than the focus ring. In particular, the oxide film such as the silicon dioxide film formed on the wafer is the target of processing in the plasma treatment apparatus having the configuration described above, where the insulating ring and the like made from quartz also tends to be etched when etching the oxide film and the frequency of replacement becomes high.

### BRIEF DESCRIPTION OF THE DRAWINGS

FIG. 1 is a cross-sectional view schematically illustrating one example of a configuration of a plasma treatment apparatus;

FIGS. 2A and 2B are views illustrating one example of a configuration of an insulator ring coated with a protective film according to a first embodiment;

FIG. 3 is a view schematically illustrating a temporal change of a general insulator ring;

FIG. 4 is a partially enlarged cross-sectional view of a structure around the insulator ring;

FIG. 5 is a partially enlarged cross-sectional view of a structure around an insulator ring according to a second embodiment; and

FIG. 6 is a partially enlarged cross-sectional view of a structure around an insulator ring according to a third embodiment.

### DETAILED DESCRIPTION

In general, according to one embodiment, a plasma treatment apparatus, including a processing target holding unit for holding a processing target in a chamber and a plasma generation unit for plasmatizing gas introduced into the chamber, for processing the processing target using the generated plasma is provided. The processing target holding unit includes a processing target supporting member on which the processing target is mounted, a ring-shaped insulator ring arranged at an outer periphery of the processing target supporting member, and a protective film containing yttria for covering a side surface of the insulator ring and a surface (hereinafter referred to as plasma exposed surface) exposed to the plasma excluding the side surface. The protective film is formed thicker on the plasma exposed surface than on the side surface of the insulator ring.

The plasma treatment apparatus according to the embodiment will be hereinafter described in detail with reference to the accompanied drawings. It should be recognized that the present invention is not to be limited by the embodiments.

### First Embodiment

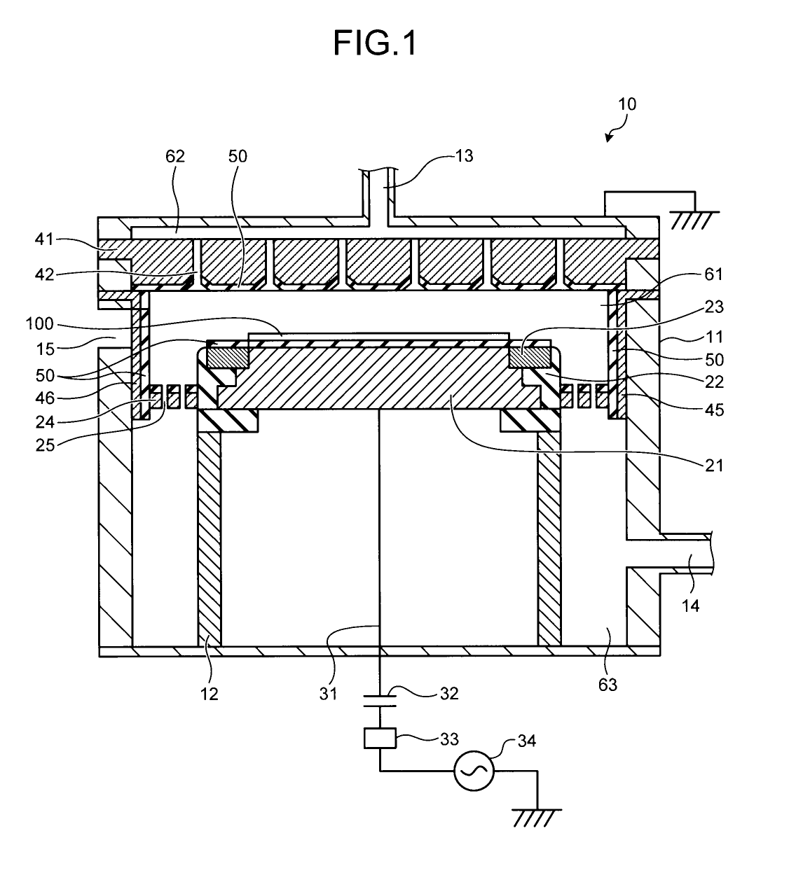

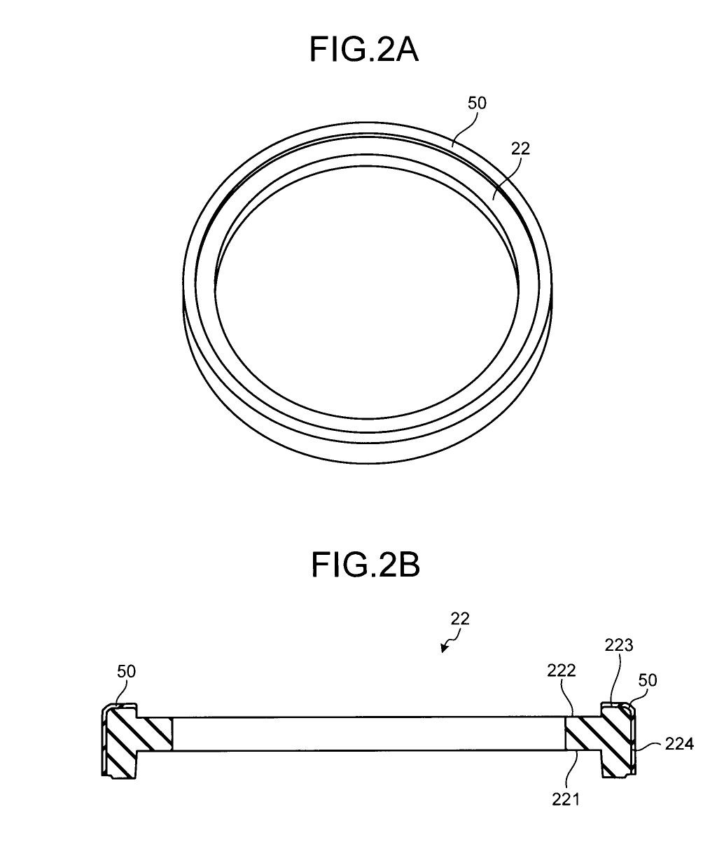

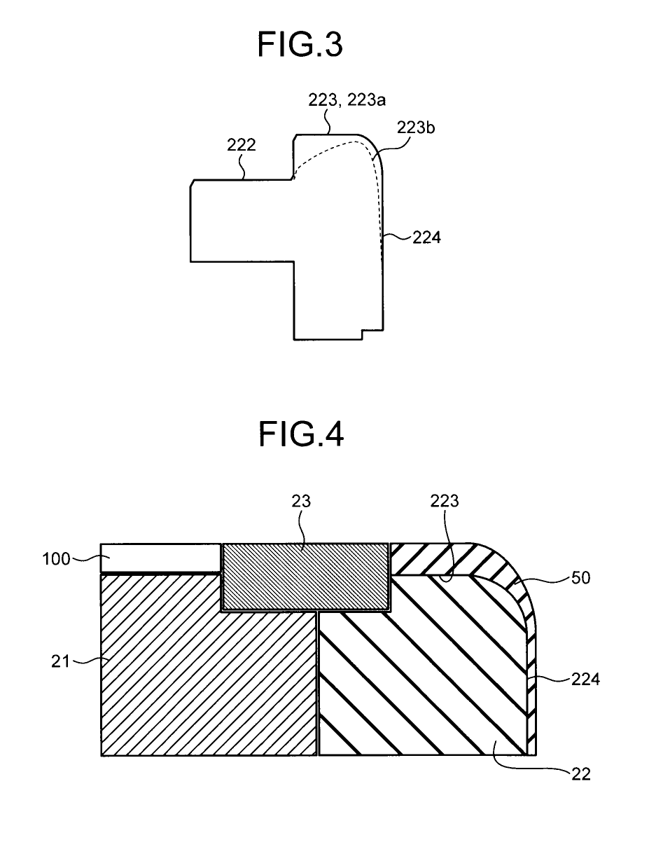

FIG. 1 is a cross-sectional view schematically illustrating one example of a configuration of a plasma treatment apparatus, and FIGS. 2A and 2B are views illustrating one example of a configuration of an insulator ring coated with a protective film according to a first embodiment, FIG. 2A being a perspective view and FIG. 2B being a cross-sectional view. FIG. 3 is a view schematically illustrating a temporal change of a general insulator ring, and FIG. 4 is a partially enlarged cross-sectional view of a structure around the insulator ring. An RIE (Reactive Ion Etching) apparatus is illustrated herein as a plasma treatment apparatus 10.

As illustrated in FIG. 1, the plasma treatment apparatus 10 includes an aluminum chamber 11 configured to be in an air tight state. A supporting table 21 functioning as a lower electrode for horizontally supporting a wafer 100 serving as a processing target is arranged in the chamber 11. A holding mechanism (not illustrated) such as an electrostatic chuck mechanism for electrostatically adsorbing the wafer 100 is arranged on a surface of the supporting table 21. An insulator ring 22 is arranged to cover the peripheral edge of the side surface and the bottom surface of the supporting table 21, where a focus ring 23 is arranged on the outer periphery at the upper side of the supporting table 21 covered with the insulator ring 22. The focus ring 23 is a member made from a conductive material that is arranged to adjust the electric field so that the electric field does not deflect with respect to a vertical direction (direction perpendicular to wafer surface) at the peripheral edge of the wafer 100 when etching the wafer 100.

The supporting table 21 is supported through the insulator ring 22 on a supporting unit 12, which projects out in a tubular form to vertically upper side from the bottom wall at near the middle of the chamber 11, so as to be positioned near the middle of the chamber 11. A baffle plate 24 is arranged between the insulator ring 22 and the side wall of the chamber 11. The baffle plate 24 has a plurality of gas discharge holes 25 that passes through in a thickness direction of the plate. A power supply line 31 for supplying radio frequency power is connected to the supporting table 21, and a blocking capacitor 32, a matching box 33, and a radio frequency power supply 34 are connected to the power supply line 31. The radio frequency power of a predetermined frequency is supplied from the radio frequency power supply 34 to the supporting table 21 at the time of plasma treatment.

A shower head 41 functioning as an upper electrode is arranged at the upper part of the supporting table 21 so as to face the supporting table 21 functioning as the lower electrode. The shower head 41 is fixed to the side wall near the upper part of the chamber 11 with a predetermined distance from the supporting table 21 so as to face the supporting table 21 in parallel. According to such structure, the shower head 41 and the supporting table 21 configure a pair of parallel plate electrodes. The shower head 41 has a plurality of gas discharge ports 42 that passes through in a thickness direction of the plate.

A gas supply port 13, to which the processing gas used in the plasma treatment is supplied, is arranged near the upper part of the chamber 11, and a gas supply device (not illustrated) is connected to the gas supply port 13 through a piping.

A gas exhaust port 14 is formed in the chamber 11 at lower than the supporting table 21 and the baffle plate 24, and a vacuum pump or an exhaust unit (not illustrated) is connected to the gas exhaust port 14 through a piping.

A deposit shield 45 for preventing attachment of deposited materials produced at the time of plasma treatment to the side wall of the chamber 11 is arranged on the side wall of the chamber 11 in the region partitioned between the baffle plate 24 and the shower head 41. Furthermore, an opening 15 for taking in and out the wafer 100 is formed at a side wall portion at a predetermined position of the chamber 11, and a shutter 46 is arranged at a portion of the deposit shield 45 corresponding to the opening 15. The shutter 46 acts to partition the exterior and the interior of the chamber 11, and is opened/closed to connect the opening 15 and the inside of the chamber 11 when taking in and out the wafer 100.

The region partitioned with the supporting table 21 and the baffle plate 24, and the shower head 41 in the chamber 11 becomes a plasma treatment chamber 61, the region at the upper part of the chamber 11 partitioned with the shower head 41 becomes a gas supply chamber 62, and the region at the lower part of the chamber 11 partitioned with the supporting table 21 and the baffle plate 24 becomes a gas exhaust chamber 63.

The outline of the processes in the plasma treatment apparatus 10 configured as above will be described below. First, the wafer 100 to be processed is mounted on the supporting table 21, and fixed with the electrostatic chuck mechanism, for example. The inside of the chamber 11 is then vacuumed with the vacuum pump (not illustrated) connected to the gas exhaust port 14. In this case, the entire chamber 11 is vacuumed by the vacuum pump connected to the gas exhaust port 14 since the gas exhaust chamber 63 and the plasma treatment chamber 61 are connected by the gas discharge hole 25 formed in the baffle plate 24.

When the inside of the chamber 11 reaches a predetermined pressure thereafter, the processing gas is supplied from the gas supply device (not illustrated) to the gas supply chamber 62 and supplied to the plasma treatment chamber 61 through the gas discharge port 42 of the shower head 41 since the plasma treatment chamber 61 and the gas supply chamber 62 are connected by the gas discharge port 42 of the shower head 41. When the pressure in the plasma treatment chamber 61 reaches a predetermined pressure, a radio frequency voltage is applied on the supporting table 21 (lower electrode) with the shower head 41 (upper electrode) grounded to generate plasma in the plasma treatment chamber 61. The potential gradient is formed between the plasma and the wafer 100 according to the auto-bias by the radio frequency voltage on the lower electrode side and the ions in the plasma gas are accelerated to the supporting table 21, so that an anisotropic etching process is carried out.

At the time of the anisotropic etching process, not only the wafer 100 but also the focus ring 23 and the insulator ring 22 are also etched by ions and radicals. Therefore, the surface of the configuring member on the side that contacts the plasma generating region, that is, the surface of the configuring member of the plasma treatment chamber 61 is easily degraded by being exposed to plasma and hence includes a protective film 50 having etching resistance at the time of the plasma treatment.

The insulator ring 22 formed with the protective film 50 according to the present embodiment will now be described. As illustrated in FIGS. 2A and 2B, the insulator ring 22 has a circular ring shape, and is made from an insulating material such as quartz (SiO₂). The insulator ring 22 includes a lower cutout 221 arranged on the lower surface side so as to cover the outer periphery of the supporting table 21 and to be fixed with a step difference provided at the outer periphery of the supporting table 21 such that the lower electrode to apply the radio frequency and the focus ring are insulated from the apparatus main body, and an upper cutout 222 arranged on the upper surface side so as to fix the focus ring 23. The protective film 50 is formed in a region etched at the time of plasma treatment with the insulator ring 22, and is formed from an upper surface section 223 excluding the upper cutout 222 to a side surface section 224 in this example. As the plasma is generated between the shower head 41 (upper electrode) and the supporting table 21 (lower electrode), the upper surface section 223 becomes the plasma exposed surface.

A coated film (hereinafter referred to as yttria film) containing yttrium oxide particles can be used as the protective film 50. Any film can be used as long as it is an yttria film, but an yttria film (hereinafter referred to as yttria film in semi-molten state) containing yttrium oxide particles in which the adjacent particles where at least the surface of the particle is in a molten state are bonded and solidified, and in which the grain boundary of one part is not recognized is desirable. The yttria film in semi-molten state contains yttrium oxide particles, where the film thickness is greater than or equal to 10 μm, the film density is higher than or equal to 90%, the yttrium oxide particle, in which the grain boundary can be recognized, existing in a unit area of 200 μm×200 μm is contained at an area rate of 0 to 80%, and the yttrium oxide particle, in which the grain boundary cannot be recognized, is contained at an area rate of 20 to 100%.

The film thickness of the yttria film is preferably greater than or equal to 10 μm. The effect of arranging the yttria film is not sufficiently obtained if less than 10 μm, and it may become the cause of film stripping. The upper limit in the thickness of the yttria film is not particularly limited, but further effect cannot be achieved if too thick, and cracks may easily form due to accumulation of internal stress that may become a factor in increase in cost. The thickness of the yttria film is thus between 10 and 200 μm, and more preferably between 50 and 150 μm.

The film density is higher than or equal to 90%, and preferably higher than or equal to 95%, and more preferably higher than or equal to 99% and lower than or equal to 100%. If voids exist in great numbers in the yttria film, corrosion such as plasma attack may advance from such voids and may lower the lifespan of the oxide coating film. It is desirable that the voids are few particularly at the surface of the yttria film.

The film density is an opposite word of porosity, where film density of higher than or equal to 90% means the same as porosity of smaller than or equal to 10%. The method of measuring the film density includes cutting the oxide coating film in the film thickness direction, taking an enlarged photograph of 500 times of the cross-sectional tissue with an optical microscope, and calculating the area rate of the void in the photograph. The film density is then calculated with “film density (%)=100−area rate of void”. The area of the unit area 200 μm×200 μm is analyzed for the calculation of the film density. If the film thickness is thin, a plurality of areas is measured until the total unit area becomes 200 μm×200 μm.

Furthermore, as the breakdown heat caused by impact may become insufficient if the “yttrium oxide particles in which grain boundary can be recognized” exceeds 80% in area rate, rapid cooling state is realized in deposition thus lowering the density of the film and lowering the bonding force, and producing cracks in some cases, and hence the “yttrium oxide particles in which grain boundary can be recognized” is desirably between 0 and 80% in area rate.

The surface roughness Ra of the yttria film is preferably smaller than or equal to 3 μm. If the surface bumps of the yttria film are large, plasma attack and the like tend to easily concentrate thus reducing the lifespan of the film. The measurement of the surface roughness Ra complies with JIS-B-0601-1994. The surface roughness Ra is preferably smaller than or equal to 2 μm.

Furthermore, the average particle diameter of the yttrium oxide particle in which the grain boundary can be recognized is smaller than or equal to 2 μm, and the average particle diameter of the entire yttrium oxide particle including the yttrium oxide particle in which the grain boundary cannot be recognized is preferably smaller than or equal to 5 μm.

Such protective film 50 can be formed on the upper surface section 223 and the side surface section 224 of the insulator ring 22 using a thermal spraying method, a chemical vapor deposition (CVD) method, an aerosol deposition method, a cold spraying method, a gas deposition method, an electrostatic powder impact deposition method, an impact sintering method and the like.

In particular, the yttria film in semi-molten state can be formed by accelerating an injection speed of the yttrium oxide particles in a state in which the yttrium oxide particles are not melted or only the surface layer is melted, and controlling the speed at high speed of higher than or equal to a critical speed at which the particles start to deposit for film forming in the impact sintering method of supplying slurry containing the yttria particles to combustion flame and injecting particles from the injection nozzle, colliding the particles to the base material at high speed (e.g., higher than or equal to sound speed) and sintering and bonding the particles with the fragmenting heat of the particles caused by the collision to form the coating film. The yttrium oxide particles in the yttria film thus tend to easily form the coating film in a more fragmented shape than the particle shape of the base powder. The yttrium oxide particle, which surface layer is melted, bonds with the adjacent yttrium oxide particle with the fragmenting heat of when colliding with the base material, thus forming the yttria film containing the yttrium oxide particles in which the grain boundary cannot be recognized. In this case, not only the surface layer of the yttrium oxide particle but the entire particle may be melted with the fragmenting heat generated at the time of collision of the yttrium oxide particle to the base material, in which case, the yttria film is also similarly formed. The yttrium oxide particle in which the surface layer is not molten may have at least the surface layer melted with the fragmenting heat of when colliding with the base material, whereby the yttria film containing the yttrium oxide particles in which the grain boundary between the adjacent yttrium oxide particles cannot be recognized is formed. As the raw powder is not melted and injected as in thermal spraying by using high speed injection, the yttrium oxide particle serving as the raw powder can be deposited while substantially maintaining the powder shape. As a result, the stress inside the film is not generated, and the yttria film that is closely packed (high film density) and has strong bonding force can be formed.

The area rate of the particle in which the grain boundary can be recognized and the particle in which the grain boundary cannot be recognized in the yttria film formed on the base material can be adjusted by adjusting the slurry supply position of when supplying the slurry to the combustion flame and the distance between the injection nozzle and the base material of when injecting the particles.

When etching the oxide film with the RIE apparatus or the like using the insulator ring 22 not formed with the protective film 50, the insulator ring 22 is also simultaneously etched with the etching of the oxide film formed on the wafer 100. In particular, in the manufacturing of the semiconductor device, the silicon dioxide film is often used as the oxide film, and hence the insulator ring 22 of the same composition tends to be similarly etched when etching the silicon dioxide film. As illustrated in FIG. 3, in a new insulator ring 22, the height of the upper surface section 223 is the same anywhere in the radial direction of the insulator ring 22, as illustrated with a contour 223a, but the upper surface section 223 is etched towards the upper cutout 222 side with use thus becoming a contour 223b. The upper surface section 223 exposed to plasma (closer to plasma) is more easily etched than the side surface section 224.

As illustrated in FIG. 4, in the first embodiment, the thickness of the protective film 50 formed on the upper surface section 223 that is likely to be etched (closer to plasma) than the side surface section 224 that is less likely to be etched (distant from plasma) during the plasma treatment is formed thick. For instance, the thickness of the protective film 50 of the upper surface section 223 may be 100 μm and the thickness of the protective film 50 of the side surface section 224 may be 50 μm. With the insulator ring 22 formed with the protective film 50, the etching resistance is enhanced and the insulator ring 22 to be protected is not etched as illustrated in FIG. 3, and hence the lifespan of the insulator ring 22 can be extended compared to when configured only with quartz.

Therefore, according to the first embodiment, as the protective film 50 including the yttria film or the material having high plasma resistance is formed such that the upper surface section 223 becomes thicker than the side surface section 224 of the insulator ring 22, the effects of being less likely to be etched during the plasma treatment and extending the lifespan of the insulator ring 22 compared to the insulator ring 22 made of quartz can be obtained. If the insulator ring 22 is made from quartz as in a general plasma treatment apparatus, the insulator ring 22 is also etched at substantially the same percentage with the etching of the oxide film formed on the wafer 100. In the insulator ring 22 having a structure adapted to include the protective film 50 according to the first embodiment, on the other hand, the amount of etching is about one of a few dozen of when the insulator ring 22 made of quartz is used. Therefore the insulator ring 22 needs to be frequently replaced when using the insulator ring 22 made of quartz, but the frequency of replacement can be reduced as the lifespan is extended compared to the prior art with the insulator ring 22 including the protective film 50 according to the first embodiment. Furthermore, the usage amount of the raw material at the time of forming the protective film 50 can be suppressed compared to when the film thicknesses are all made the same by making the thickness of the protective film 50 at the upper surface section 223 close to the plasma thicker than the thickness of the protective film 50 at the side surface section 224 distant from the plasma.

The production of dust can be suppressed at the time of the plasma treatment (etching process) compared to the insulator ring 22 made of quartz since the protective film 50 including the yttria film is formed on the upper surface section 223 and the side surface section 224 of the insulator ring 22.

Specifically, although the F series gas is generally used to etch the oxide, reaction product such as SiF₄ is generated by the etching of the insulator ring 22 if the insulator ring 22 is made from quartz as in a general plasma treatment apparatus. They may attach to the processing target as dust. However, in the insulator ring 22 including the protective film 50 consisting of the yttria film of the first embodiment, the reaction product such as YF₃ is generated by etching but YF₃ covers the insulator ring 22 without being re-evaporated as it is difficult to evaporate, and thus the insulator ring 22 becomes less likely to be etched. As a result, the reaction product can be prevented from attaching to the processing target as dust.

Furthermore, in the case of the quartz, oxygen is generated with the reaction product such as SiF₄ when etched with the F series gas, but the etching condition becomes stable and the temporal change can be suppressed as the protective film 50 including the yttria film has high etching resistance and the generation of oxygen is small compared to the quartz.

### Second Embodiment

In the first embodiment, the thickness of the protective film arranged on the upper surface section of the insulator ring is made thicker than that arranged on the side surface section, but in the second embodiment, a case in which the thickness of the protective film in the upper surface section of the insulator ring is changed will be described.

As illustrated in FIG. 3, the temporal change by the etching of the upper surface section 223 of the insulator ring 22 made of quartz is that etching is more easily carried out on the inner side (focus ring side or wafer mounting side). Thus, the thickness of the protective film 50 arranged on the upper surface section 223 of the insulator ring 22 can be changed depending on the places.

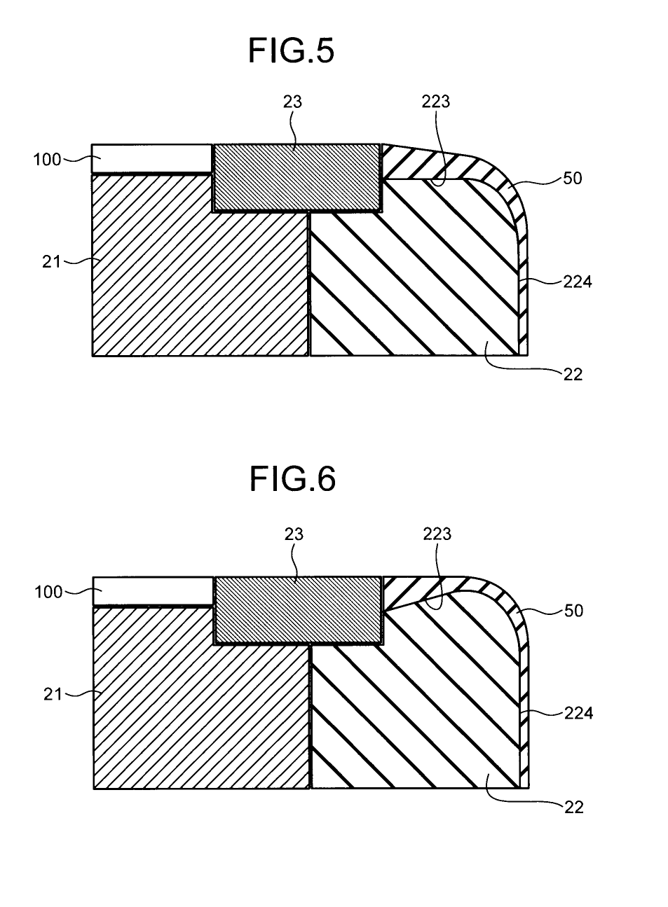

FIG. 5 is a partially enlarged cross-sectional view of a structure around the insulator ring according to the second embodiment. As illustrated in FIG. 5, the thickness of the protective film 50 is made thicker towards the inner side, and thinner towards the outer side. The upper surface section 223 other than the upper cutout 222 of the insulator ring 22 in this case is set to the same height in the radial direction of the insulator ring 22, so that the height of the upper surface of the protective film 50 becomes higher from the outer side towards the inner side of the insulator ring 22. Similar to the first embodiment, the protective film 50 can be formed by a film containing the yttria film.

In the second embodiment, the thickness of the protective film 50 formed on the upper surface section 223 of the insulator ring 22 is changed depending on the places, and hence the thickness of the protective film 50 is made thick in places that are likely to be etched and the thickness of the protective film 50 is made thin in places that are less likely to be etched. The thickness of the protective film 50 at the place that is less likely to be etched thus can be made thin compared to the first embodiment, whereby the time required to form the protective film 50 can be reduced and the usage amount of raw material used for the protective film 50 can be further suppressed.

### Third Embodiment

In the third embodiment as well, a case of changing the thickness of the protective film in the upper surface section of the insulator ring will be described, similar to the second embodiment.

FIG. 6 is a partially enlarged cross-sectional view of a structure around the insulator ring according to the third embodiment. In the third embodiment as well, the thickness of the protective film 50 is made thicker towards the inner side and thinner towards the outer side, similar to FIG. 5, but the height of the upper surface of the protective film 50 in the radial direction of the insulator ring 22 after the formation of the protective film 50 on the upper surface section 223 other than the upper cutout 222 of the insulator ring 22 is the same. In other words, the upper surface section 223 of the insulator ring 22 is configured to have an inclination that declines from the outer side towards the inner side. The degree of inclination of the upper surface section 223 of the insulator ring 22 can be set to match the temporal change at the time of etching in the insulator ring 22 made of quartz of when the protective film 50 is not formed illustrated in FIG. 3. The protective film 50 can be formed by a film containing the yttria film, similar to the first embodiment.

The third embodiment has effects similar to the second embodiment.

In the description made above, the RIE apparatus has been described for the plasma treatment apparatus 10 by way of example, but the embodiments described above may be applied to a general treatment apparatus and a general semiconductor manufacturing apparatus such as a resist stripping apparatus and a CDE (Chemical Dry Etching) apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A plasma treatment apparatus, comprising a processing target holding unit configured to hold a processing target in a chamber and a plasma generation unit configured to plasmatize gas introduced into the chamber, configured to process the processing target using the generated plasma, wherein
the processing target holding unit includes:
a processing target supporting member on which the processing target is mounted;
a ring-shaped insulator ring arranged at an outer periphery of the processing target supporting member; and
a protective film containing yttria configured to cover a side surface of the insulator ring and a surface (hereinafter referred to as plasma exposed surface) exposed to the plasma excluding the side surface, wherein
the protective film is formed thicker on the plasma exposed surface than on the side surface of the insulator ring.

2. The plasma treatment apparatus according to claim 1, wherein the protective film is formed so that a thickness on the plasma exposed surface of the insulator ring becomes thicker from an outer peripheral side towards a center side.

3. The plasma treatment apparatus according to claim 2, wherein
the plasma exposed surface of the insulator ring is substantially parallel to a mounting surface of the processing target of the processing target supporting member, and
an upper surface of the protective film is inclined to become higher from the outer peripheral side towards the center side of the insulator ring.

4. The plasma treatment apparatus according to claim 2, wherein
the plasma exposed surface of the insulator ring is inclined to become lower from the outer peripheral side towards the center side of the insulator ring, and
an upper surface of the protective film is substantially parallel to a mounting surface of the processing target of the processing target supporting member.

5. The plasma treatment apparatus according to claim 1, wherein a thickness of the protective film formed on the plasma exposed surface of the insulator ring is constant.

6. The plasma treatment apparatus according to claim 1, wherein the protective film contains yttrium oxide particles, has a film thickness of greater than or equal to 10 μm and smaller than or equal to 20 μm, and a film density of higher than or equal to 90%, the yttrium oxide particle in which a grain boundary is recognizable existing in a unit area of 200 μm×200 μm is contained at an area rate of 0 to 80%, and the yttrium oxide particle in which the grain boundary is not recognizable is contained at an area rate of 20 to 100%.

7. The plasma treatment apparatus according to claim 6, wherein an average particle diameter of the yttrium oxide particle in which the grain boundary is recognizable is smaller than or equal to 2 μm, and an average particle diameter of the yttrium oxide particle including the yttrium oxide particle in which the grain boundary is not recognizable is smaller than or equal to 5 μm.

8. The plasma treatment apparatus according to claim 1, wherein a surface roughness Ra of the protective film is smaller than or equal to 3 μm.

9. The plasma treatment apparatus according to claim 1, wherein the plasma treatment apparatus is an RIE apparatus, a resist stripping apparatus, or a CDE apparatus.

10. The plasma treatment apparatus according to claim 1, wherein the processing target holding unit further includes a focus ring made of a conductive material configured to adjust an electric field at a peripheral edge of the processing target in an upper part of a region including a boundary of the processing target supporting member and the insulator ring.

11. The plasma treatment apparatus according to claim 10, wherein
a recess is arranged in the processing target supporting member and the insulator ring in a region where the focus ring is mounted, and
the protective film is not arranged on the recess of the insulator ring.
